(19) United States
(12) Patent Application Publication
(10) Pub. No.: US 2026/0307021 A1
(43) Pub. Date: Oct. 8, 2026

(54) GAS SUPPLY DEVICE

(71) Applicants: Samsung Display Co., Ltd., Yongin-si (KR); BMI TECH Co., LTD., Yongin-si (KR)

(72) Inventors: Myung Hoon KIM, Yongin-si (KR); Ha Neul KO, Anseong-si (KR); Jae Ki PARK, Osan-si (KR); Hyeon June HWANG, Yongin-si (KR); Jong Sub CHOI, Yongin-si (KR)

(21) Appl. No.: 19/414,667

(22) Filed: Dec. 10, 2025

(30) Foreign Application Priority Data
Apr. 4, 2025 (KR) 10-2025-0044067

(51) Int. Cl. B01F 23/10; B01F 35/213; B01F 35/221; B01F 35/71

(52) U.S. Cl. CPC B01F 23/191; B01F 35/213; B01F 35/22141; B01F 35/718051

(57) ABSTRACT

A gas supply device includes: first and second mixing units configured to mix first and second gases to generate a mixed gas; a first supply line connected to the first mixing unit; a second supply line connected to the second mixing unit; a third supply line connected to the first and second supply lines and providing a passage through which the mixed gas generated by the first and/or second mixing units flows; a storage tank connected to the third supply line and configured to store one of the mixed gases; a fourth supply line connected to the storage tank and providing a passage through which the mixed gas stored in the storage tank flows; and a controller configured to control the first and second mixing units so that the mixed gas is selectively generated in either the first or second mixing units.

### CROSS-REFERENCE TO RELATED APPLICATION

The present application claims priority to and the benefit of Korean Patent Application No. 10-2025-0044067, filed on Apr. 04, 2025, in the Korean Intellectual Property Office, the entire disclosure of which is incorporated herein by reference.

### BACKGROUND

### 1. Field

Aspects of embodiments of the present disclosure relate to a gas supply device.

### 2. Description of the Related Art

Thin and light flat panel display devices are widely used as display devices. Examples of flat panel display devices include a liquid crystal display (LCD), a plasma display panel (PDP), an organic light-emitting diode (OLED) display, and the like.

During manufacturing of the flat panel display devices, various gases are supplied to and used in manufacturing equipment for the flat panel display devices. In particular, mixed gas of hydrogen and nitrogen used in such manufacturing equipment plays an important role in protecting the manufacturing equipment or maintaining the reaction environment. Such mixed gases are supplied to each manufacturing equipment by a gas supply device.

### SUMMARY

Embodiments of the present disclosure provide a gas supply device that may continuously and stably supply a mixed gas of nitrogen and hydrogen to a process chamber for manufacturing a display device.

However, aspects and features of the present disclosure are not limited to those described herein. The above and other aspects and features of the present disclosure will become more apparent to one of ordinary skill in the art to which the present disclosure pertains by referencing the detailed description of the present disclosure given below.

According to an embodiment of the present disclosure, a gas supply device includes a first mixing unit configured to mix a first gas and a second gas to generate a mixed gas, a first supply line connected to the first mixing unit and providing a passage through which the mixed gas generated by the first mixing unit flows, a second mixing unit configured to mix the first gas and the second gas to generate the mixed gas, a second supply line connected to the second mixing unit and providing a passage through which the mixed gas generated by the second mixing unit flows, a third supply line connected to the first supply line and the second supply line and providing a passage through which one of the mixed gas generated by the first mixing unit and the mixed gas generated by the second mixing unit flows, a storage tank connected to the third supply line and configured to store one of the mixed gas generated by the first mixing unit and the mixed gas generated by the second mixing unit, a fourth supply line connected to the storage tank and providing a passage through which the mixed gas stored in the storage tank flows, and a controller configured to control the first mixing unit and the second mixing unit so that the mixed gas is selectively generated in either the first mixing unit or the second mixing unit.

The gas supply device further includes a first flow controller disposed on the first supply line and configured to control a flow rate of the mixed gas generated in the first mixing unit flowing through the first supply line, a second flow controller disposed on the second supply line and configured to control a flow rate of the mixed gas generated in the second mixing unit and flowing through the second supply line, a third flow controller disposed on the third supply line and configured to control a flow rate of one of the mixed gas generated in the first mixing unit and the mixed gas generated in the second mixing unit and flowing through the third supply line, and a fourth flow controller disposed on the fourth supply line and configured to control a flow rate of the mixed gas stored in the storage tank and flowing through the fourth supply line.

The gas supply device further includes a first main exhaust line connected to the first mixing unit and providing a passage for discharging some of the mixed gas generated in the first mixing unit, a second main exhaust line connected to the second mixing unit and providing a passage for discharging some of the mixed gas generated in the second mixing unit, a third main exhaust line connected to the storage tank and providing a passage for discharging some of the mixed gas stored in the storage tank, and a fourth main exhaust line connected to the first main exhaust line, the second main exhaust line, and the third main exhaust line and providing a passage for discharging some of the mixed gas generated in the first mixing unit, some of the mixed gas generated in the second mixing unit, and some of the mixed gas stored in the storage tank.

Each of the first mixing unit and the second mixing unit includes a first gas supply unit configured to supply the first gas, a first gas supply line connected to the first gas supply unit and providing a passage through which the first gas supplied from the first gas supply unit flows, a second gas supply unit configured to supply the second gas, a second gas supply line connected to the second gas supply unit and providing a passage through which the second gas supplied from the second gas supply unit flows, a first mixing line connected to the first gas supply line and the second gas supply line and providing a passage through which the first gas flowing through the first gas supply line and the second gas flowing through the second gas supply line flow, a first mixing unit connected to the first mixing line and having a storage space for mixing and storing the first gas and second gas flowing through the first mixing line formed therein, a second mixing line connected to the first mixing unit and providing a passage through which the mixed gas mixed in the first mixing unit flows, a second mixing unit connected to the second mixing line and having a storage space for remixing and storing the mixed gas flowing through the second mixing line

formed therein, and a third mixing line connected to the second mixing unit and providing a passage through which the mixed gas mixed in the second mixing unit flows.

The storage space of the first mixing unit is smaller than the storage space of the second mixing unit.

Each of the first mixing unit and the second mixing unit includes a first sensor disposed on the second mixing line and configured to determine a mixing ratio of the mixed gas flowing through the second mixing line, a second sensor disposed on the third mixing line and configured to determine the mixing ratio of the mixed gas flowing through the third mixing line, a first exhaust line which branches off from the second mixing line downstream of the first sensor in a flow direction of the mixed gas and provides a passage for discharging the mixed gas flowing through the second mixing line, and a second exhaust line which branches off from the third mixing line downstream of the second sensor in the flow direction of the mixed gas, is connected to the first exhaust line, and provides a passage for discharging the mixed gas flowing through the third mixing line to the first exhaust line.

Each of the first mixing unit and the second mixing unit includes a first gas flow controller disposed on the first gas supply line and is configured to control the flow rate of the first gas flowing through the first gas supply line, a second gas flow controller disposed on the second gas supply line and is configured to control the flow rate of the second gas flowing through the second gas supply line, and a mixed gas flow controller disposed on the third mixing line, upstream of the second sensor in the flow direction of the mixed gas, and is configured to control the flow rate of the mixed gas flowing through the third mixing line.

Each of the first mixing unit and the second mixing unit includes a first valve disposed on the first gas supply line upstream of the first gas flow controller in the flow direction of the first gas, a second valve disposed on the first gas supply line downstream of the first gas flow controller in the flow direction of the first gas, a third valve disposed on the second gas supply line upstream of the second gas flow controller in the flow direction of the second gas, a fourth valve disposed on the second gas supply line downstream of the second gas flow controller in the flow direction of the second gas, a fifth valve disposed on the second mixing line downstream of a point from which the first exhaust line branches off in the flow direction of the mixed gas, a sixth valve disposed on the third mixing line upstream of the mixed gas flow controller in the flow direction of the mixed gas, a seventh valve disposed on the third mixing line between the mixed gas flow controller and the second sensor, an eighth valve disposed on the third mixing line downstream of a point from which the second exhaust line branches off in the flow direction of the mixed gas, a ninth valve disposed on the first exhaust line upstream of a point to which the second exhaust line is connected in the flow direction of the mixed gas, and a tenth valve disposed on the first exhaust line downstream of a point to which the second exhaust line is connected in the flow direction of the mixed gas. The controller is configured to control the opening and closing of the valves according to one or more operating modes.

The one or more operating modes include a mixing mode, and during the mixing mode, the controller is configured to: open the first valve, the second valve, the third valve, and the fourth valve so that the first gas and the second gas flow to the first mixing unit; open the fifth valve so that the mixed gas stored in the first mixing unit flows to the second mixing unit; open the sixth valve, the seventh valve, and the eighth valve so that the mixed gas stored in the second mixing unit flows to the third mixing line; and close the ninth valve and the tenth valve so that the first exhaust line is closed.

The one or more operating modes include a first exhaust mode, and during the first exhaust mode, the controller is configured to: open the first valve, the second valve, the third valve, and the fourth valve so that the first gas and the second gas flow to the first mixing unit; close the fifth valve and open the ninth and tenth valves so that the mixed gas flowing through the second mixing line flows to the first exhaust line; and close the sixth valve, the seventh valve, and the eighth valve so that the mixed gas stored in the second mixing unit does not flow to the third mixing line.

When the mixing ratio of the mixed gas flowing through the second mixing line determined by the first sensor does not match a reference mixing ratio, the controller is configured to control the opening and closing of the valves according to the first exhaust mode.

The one or more operating modes include a second exhaust mode, and during the second exhaust mode, the controller is configured to: open the first valve, the second valve, the third valve, and the fourth valve so that the first gas and the second gas flow to the first mixing unit; open the fifth valve so that the mixed gas stored in the first mixing unit flows to the second mixing unit; open the sixth valve and the seventh valve so that the mixed gas stored in the second mixing unit flows to the third mixing line; close the ninth valve so that the mixed gas flowing through the second mixing line does not flow to the first exhaust line; and close the eighth valve and open the tenth valve so that the mixed gas flowing through the eighth mixing line flows to the first exhaust line through the second exhaust line.

When the mixing ratio of the mixed gas flowing through the third mixing line determined by the second sensor does not match the reference mixing ratio, the controller controls the opening and closing of the valves according to the second exhaust mode.

The third mixing line of the first mixing unit is connected to the first supply line, the first exhaust line of the first mixing unit is connected to the first main exhaust line, the third mixing line of the second mixing unit is connected to the second supply line, and the first exhaust line of the second mixing unit is connected to the second main exhaust line.

The storage tank has a storage space for storing one of the mixed gas generated by the first mixing unit and the mixed gas generated by the second mixing unit. The gas supply device further includes a mixed gas supply line which extends from the third supply line to the storage space of the storage tank and a supply nozzle which extends from the mixed gas supply line and having a plurality of nozzle holes formed therein.

The supply nozzle extends in a direction crossing (e.g., intersecting) a direction in which the mixed gas supply line extends.

The mixed gas supply line extends from an inner side of the storage space of the storage tank to a central region of the storage space, and the supply nozzle extends symmetrically from extension ends of the mixed gas supply line in both directions.

The plurality of nozzle holes are spaced apart from each other along an outer periphery and an extension direction of the supply nozzle.

Some of the plurality of nozzle holes are formed at the extension ends on opposite sides of the supply nozzle.

When the mixed gas stored in the storage tank exceeds a reference storage capacity, some of the mixed gas stored in the storage tank is discharged through the third main exhaust line.

The gas supply device, according to embodiments of the present disclosure, provides continuous and stable supplying of the mixed nitrogen and hydrogen gas to the process chamber for manufacturing the display device.

Aspects and features of embodiments of the present disclosure are not limited to those mentioned above and more various aspects and features are included in the following description of the present disclosure.

### BRIEF DESCRIPTION OF THE DRAWINGS

The above and other aspects and features of the present disclosure will become more apparent by describing, in detail, example embodiments thereof with reference to the attached drawings, in which:

FIG. 1 is a block diagram describing a gas supply device according to an embodiment of the present disclosure;

FIG. 2 is a block diagram describing a first mixing unit and a second mixing unit shown in FIG. 1;

FIG. 3 is a perspective view of a storage tank shown in FIG. 1;

FIGS. 4-6 are diagrams showing a supply nozzle shown in FIG. 3;

FIG. 7 is a diagram showing a state in which the mixed gas is generated only in the first mixing unit shown in FIG. 1;

FIG. 8 is a diagram showing a state in which the first mixing unit shown in FIG. 2 operates in a mixing mode;

FIG. 9 is a diagram showing a state in which some of the mixed gas generated from the first mixing unit is discharged to a first main exhaust line shown in FIG. 1;

FIG. 10 is a diagram showing a state in which the first mixing unit shown in FIG. 2 operates in a first exhaust mode;

FIG. 11 is a diagram showing a state in which the first mixing unit shown in FIG. 2 operates in a second exhaust mode;

FIG. 12 is a diagram showing a state in which mixed gas is generated only in the second mixing unit shown in FIG. 1;

FIG. 13 is a diagram showing a state in which the second mixing unit shown in FIG. 2 operates in the mixing mode;

FIG. 14 is a diagram showing a state in which some of the mixed gas generated from the second mixing unit is discharged to a second main exhaust line shown in FIG. 1;

FIG. 15 is a diagram showing a state in which the second mixing unit shown in FIG. 2 operates in the first exhaust mode;

FIG. 16 is a diagram showing a state in which the second mixing unit shown in FIG. 2 operates in the second exhaust mode;

FIG. 17 is a diagram showing a state in which some of the mixed gas stored in the storage tank is discharged to a third main exhaust line shown in FIG. 1; and

FIG. 18 is a diagram showing a state in which no mixed gas is generated in the first mixing unit and the second mixing unit shown in FIG. 1.

### DETAILED DESCRIPTION

Aspects and features of the present disclosure, and methods to achieve them, will become apparent from the descriptions of embodiments hereinbelow with reference to the accompanying drawings. However, the present disclosure is not limited to embodiments disclosed herein but may be implemented in various different ways. Embodiments are provided to ensure that the disclosure of the present disclosure is thorough and fully conveys the scope of the present disclosure to those skilled in the art. It is to be noted that the scope of the present disclosure is defined by the claims and their equivalents.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Terms such as first, second, etc. are used to arbitrarily distinguish between the elements, and thus, these terms are not necessarily intended to indicate temporal or other prioritization of such elements. These terms are used to merely distinguish one element from another. Accordingly, as used herein, a first element may be a second element within the technical scope of the present disclosure.

As used herein, the term “and/or” includes any and all combinations of one or more of the associated listed items. Further, the use of "may" when describing embodiments of the present disclosure relates to "one or more embodiments of the present disclosure." Expressions, such as “at least one of” and “any one of,” when preceding a list of elements, modify the entire list of elements and do not modify the individual elements of the list. For example, the expression "at least one of a, b, or c" indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms "substantially," "about," and similar terms are used as terms of approximation and not as terms of degree, and are intended to account for the inherent variations in measured or calculated values that would be recognized by those of ordinary skill in the art.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or "over" the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms "includes," "including," “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Features of various example embodiments of the present disclosure may be combined partially or totally. As will be clearly appreciated by those skilled in the art, technically various interactions and operations are possible. Various example embodiments can be practiced individually or in combination.

Hereinafter, example embodiments of the present disclosure will be described in detail with reference to the accompanying drawings.

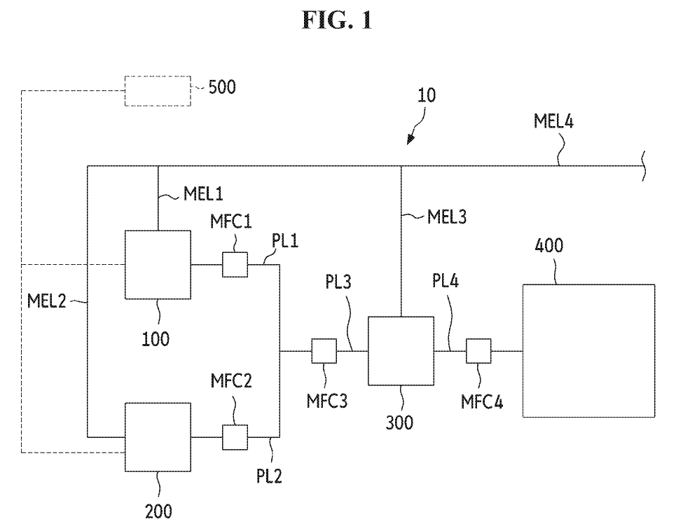

FIG. 1 is a block diagram describing a gas supply device according to an embodiment of the present disclosure.

Referring to FIG. 1, a gas supply device 10, according to an embodiment of the present disclosure, may include a first mixing unit 100, a second mixing unit 200, a first supply line PL1, a second supply line PL2, a third supply line PL3, a storage tank 300, a fourth supply line PL4, a first main exhaust line MEL1, a second main exhaust line MEL2, a third main exhaust line MEL3, a fourth main exhaust line MEL4, and a controller 500.

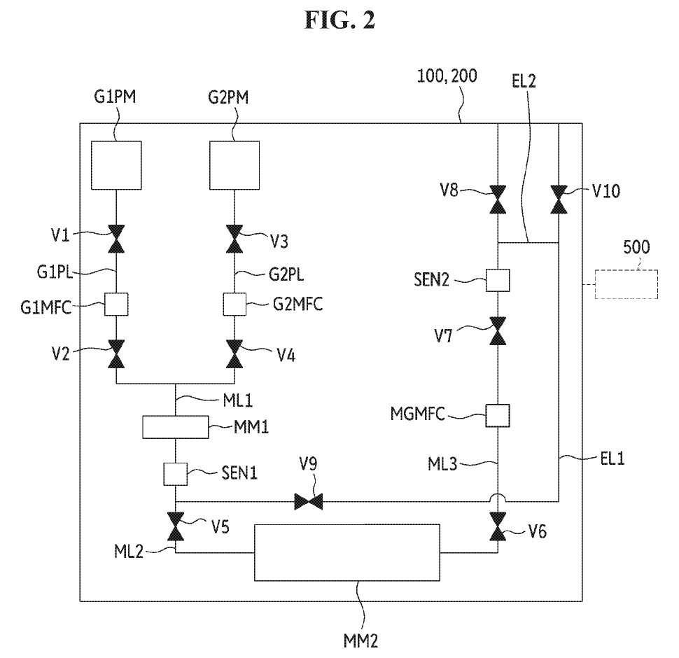

FIG. 2 is a block diagram showing the first and second mixing units shown in FIG. 1.

Referring to FIG. 2, each of the first mixing unit 100 and the second mixing unit 200 may mix a first gas and a second gas to generate a mixed gas. Each of the first mixing unit 100 and the second mixing unit 200 may include a first gas supply unit G1PM, a second gas supply unit G2PM, a first gas supply line G1PL, a second gas supply line G2PL, a first mixing line ML1, a first mixing unit MM1, a second mixing line ML2, a second mixing unit ML2, a third mixing line ML3, a first sensor SEN1, a second sensor SEN2, a first exhaust line EL1, and a second exhaust line EL2.

The first gas supply unit G1PM may supply a first gas. The first gas supply unit G1PM may be connected to a first gas supply source disposed outside the gas supply device 10 and may supply (e.g., may be configured to supply) a first gas supplied from the first gas supply source to the first mixing unit 100. The first gas may be hydrogen.

The second gas supply unit G2PM may supply a second gas. The second gas supply unit G2PM is connected to a second gas supply source disposed outside the gas supply device 10 and may supply (e.g., may be configured to supply) the second gas supplied from the second gas supply source to the second mixing unit 200. The second gas may be nitrogen.

The first gas supply line G1PL is connected to the first gas supply unit G1PM and may provide a passage through which the first gas supplied from the first gas supply unit G1PM flows. For example, the first gas supply line G1PL may be a pipe having a flow space formed therein, and one side of the first gas supply line G1PL may be connected to the first gas supply unit G1PM. The first gas supplied from the first gas supply unit G1PM may flow through an internal flow space of the first gas supply line G1PL.

The second gas supply line G2PL is connected to the second gas supply unit G2PM and may have a passage through which the second gas supplied from the second gas supply unit G2PM flows. For example, the second gas supply line G2PL may be a pipe having a flow space formed therein, and one side of the second gas supply line G2PL may be connected to the second gas supply unit G2PM. The second gas supplied from the second gas supply unit G2PM may flow through the internal flow space of the second gas supply line G2PL.

The first mixing line ML1 may provide a passage through which the first gas flowing through the first gas supply line G1PL and the second gas flowing through the second gas supply line G2PL are mixed and flow. The first mixing line ML1 may be connected to the first gas supply line G1PL and the second gas supply line G2PL. For example, the first mixing line ML1 may be provided as a pipe having a flow space formed therein, and one side of the first mixing line ML1 may be connected to the first gas supply line G1PL and the second gas supply line G2PL. The first gas flowing through the first gas supply line G1PL and the second gas flowing through the second gas supply line G2PL may flow through the internal flow space of the first mixing line ML1.

The first mixing unit MM1 is connected to the first mixing line ML1 and may mix and store the first gas and the second gas flowing through the first mixing line ML1. A storage space for storing the first gas and the second gas may be formed inside the first mixing unit MM1. The first gas and the second gas that flow to and are stored in the first mixing unit MM1 through the first mixing line ML1 may be mixed in the first mixing unit MM1.

The second mixing line ML2 may provide a passage through which the mixed gas mixed in the first mixing unit MM1 flows. The second mixing line ML2 may be connected to the first mixing unit MM1. For example, the second mixing line ML2 may be provided as a pipe having a flow space formed therein, and one side of the second mixing line ML2 may be connected to the first mixing unit MM1. The mixed gas mixed in the first mixing unit MM1 may flow through the internal flow space of the second mixing line ML2.

The second mixing unit MM2 is connected to the second mixing line ML2 and may remix (e.g., may further mix) and store the mixed gas flowing through the second mixing line ML2. A storage space for storing the remixed gas may be formed inside the second mixing unit MM2. The mixed gas which flows to and is stored in the second mixing unit MM2 through the second mixing line ML2 may be remixed in the second mixing unit MM2. The storage space of the second mixing unit MM2 may be larger than the storage space of the first mixing unit MM1. In some embodiments, the storage space of the second mixing unit MM2 may have a larger volume than the storage space of the first mixing unit MM1.

The third mixing line ML3 may provide a passage through which the mixed gas mixed in the second mixing unit MM2 flows. The third mixing line ML3 may be connected to the second mixing unit MM2. For example, the third mixing line ML3 may be provided as a pipe having a flow space formed therein, and one side of the third mixing line ML3 may be connected to the second mixing unit MM2. The mixed gas mixed in the second mixing unit MM2 may flow through the internal flow space of the third mixing line ML3. The third mixing line ML3 of the first mixing unit 100 may be connected to the first supply line PL1, and the third mixing line ML3 of the second mixing unit 200 may be connected to the second supply line PL2.

The first sensor SEN1 may be disposed on the second mixing line ML2. The first sensor SEN1 may sense a mixing ratio of the mixed gas flowing through the second mixing line ML2. The first sensor SEN1 may transfer (e.g., may communicate) the sensed (e.g., the measured or determined) mixing ratio of the mixed gas flowing through the second mixing line ML2 to the controller 500.

The second sensor SEN2 may be disposed on the third mixing line ML3. The second sensor SEN2 may sense the mixing ratio of the mixed gas flowing through the third mixing line ML3. The second sensor SEN2 may transfer the sensed mixing ratio of the mixed gas flowing through the third mixing line ML3 to the controller 500.

The first exhaust line EL1 may branch off from the second mixing line ML2. For example, the first exhaust line EL1 may be provided as a pipe having a flow space formed therein, and one side of the first exhaust line EL1 may be connected to the second mixing line ML2. One side of the first exhaust line EL1 may be connected to the second mixing line ML2 downstream of the first sensor SEN1 in a flow direction of the mixed gas. The first exhaust line EL1 may provide a passage for discharging the mixed gas flowing through the second mixing line ML2. The first exhaust line EL1 of the first mixing unit 100 may be connected to the first main exhaust line MEL1, and the second exhaust line EL2 of the second mixing unit 200 may be connected to the second main exhaust line MEL2.

The second exhaust line EL2 may branch off from the third mixing line ML3 and may be connected to the first exhaust line ML1. For example, the second exhaust line EL2 may be provided as a pipe having a flow space formed therein, and one side of the second exhaust line EL2 is connected to the third mixing line ML3, and the other side of the second exhaust line EL2 may be connected to the first exhaust line EL1. One side of the second exhaust line EL2 may be connected to the third mixing line ML3 downstream of the second sensor SEN1 in the flow direction of the mixed gas. The second exhaust line EL2 may provide a passage for discharging the mixed gas flowing through the third mixing line ML3 to the first exhaust line EL1.

Each of the first mixing unit 100 and the second mixing unit 200 may further include a first gas flow controller G1MFC, a second gas flow controller G2MFC, a mixed gas flow controller MGMFC, a first valve V1, a second valve V2, a third valve V3, a fourth valve V4, a fifth valve V5, a sixth valve V6, a seventh valve V7, an eighth valve V8, a ninth valve V9, and a tenth valve V10.

The first gas flow controller G1MFC may be disposed on the first gas supply line G1PL. The first gas flow controller G1MFC may control the flow rate of the first gas flowing through the first gas supply line G1PL. The first gas flow controller G1MFC may control the flow rate of the first gas flowing through the first gas supply line G1PL so that the flow rate of the first gas flowing from the first gas supply line G1PL is equal to the flow rate of the second gas flowing through the second gas supply line G2PL.

The second gas flow controller G2MFC may be disposed on the second gas supply line G2PL. The second gas flow controller G2MFC may control the flow rate of the second gas flowing through the second gas supply line G2PL. The second gas flow controller G2MFC may control the flow rate of the second gas flowing through the second gas supply line G2PL so that the flow rate of the second gas flowing from the second gas supply line G2PL is equal to the flow rate of the first gas flowing through the first gas supply line G1PL.

The mixed gas flow controller MGMFC may be disposed on the third mixing line ML3 and may be disposed upstream of the second sensor SEN2 in the flow direction of the mixed gas. The mixed gas flow controller MGMFC may control the flow rate of the mixed gas flowing through the third mixing line ML3.

The first valve V1 and the second valve V2 may open and close the first gas supply line G1PL. The first valve V1 may be disposed on the first gas supply line G1PL upstream of the first gas flow controller G1MFC in the flow direction of the first gas, and the second valve V2 may be disposed on the first gas supply line G1PL downstream of the first gas flow controller G1MFC in the flow direction of the first gas.

The third valve V3 and the fourth valve V4 may open and close the second gas supply line G2PL. The third valve V3 may be disposed on the second gas supply line G2PL upstream of the second gas flow controller G2MFC in the flow direction of the second gas, and the fourth valve V4 may be disposed on the second gas supply line G2PL downstream of the second gas flow controller G2MFC in the flow direction of the second gas.

The fifth valve V5 may open and close the second mixing line ML2. The fifth valve V5 may be disposed on the second mixing line ML2 downstream of a point at where the first exhaust line EL1 branches off in the flow direction of the mixed gas.

The sixth valve V6, the seventh valve V7, and the eighth valve V8 may open and close the third mixing line ML3. The sixth valve V6 may be disposed on the third mixing line ML3 upstream of the mixed gas flow controller MGMFC in the flow direction of the mixed gas, the seventh valve V7 may be disposed on the third mixing line ML3 between the mixed gas flow controller MGMFC and the second sensor SEN2, and the eighth valve V8 may be disposed on the third mixing line ML3 downstream of the point at where the second exhaust line EL2 branches off in the flow direction of the mixed gas.

The ninth valve V9 and the tenth valve V10 may open and close the first exhaust line EL1. The ninth valve V9 may be disposed on the first exhaust line EL1 upstream of a point at where the second exhaust line EL2 is connected in the flow direction of the mixed gas, and the tenth valve V10 may be disposed on the first exhaust line EL1 downstream of a point at where the second exhaust line EL2 is connected in the flow direction of the mixed gas.

Referring to FIG. 1 again, the first supply line PL1 is connected to the first mixing unit 100 and may provide a passage through which the mixed gas generated in the first mixing unit 100 flows. The first supply line PL1 may be connected to the third mixing line ML3 of the first mixing unit 100. For example, the first supply line PL1 may be provided as a pipe having a flow space formed therein, and one side of the first supply line PL1 may be connected to the first mixing unit 100. The mixed gas generated in the first mixing unit 100 may flow through the internal flow space of the first supply line PL1.

The second supply line PL2 may be connected to the second mixing unit 200 and may provide a passage through which the mixed gas generated in the second mixing unit 200 flows. The second supply line PL2 may be connected to the third mixing line ML3 of the second mixing unit 200. For example, the second supply line PL2 may be provided as a pipe having a flow space formed therein, and one side of the second supply line PL2 may be connected to the second mixing unit 200. The mixed gas generated in the second mixing unit 200 may flow through the internal flow space of the second supply line PL2.

The third supply line PL3 may be connected to the first supply line PL1 and the second supply line PL2 and may provide a passage through which one of the mixed gas generated in the first mixing unit 100 and the mixed gas generated in the second mixing unit 200 flows. For example, the third supply line PL3 may be provided as a pipe having a flow space formed therein, and one side of the third supply line PL3 may be connected to the first supply line PL1 and the second supply line PL2. One of the mixed gas generated in the first mixing unit 100 and the mixed gas generated in the second mixing unit 200 may flow through the internal flow space of the third supply line PL3.

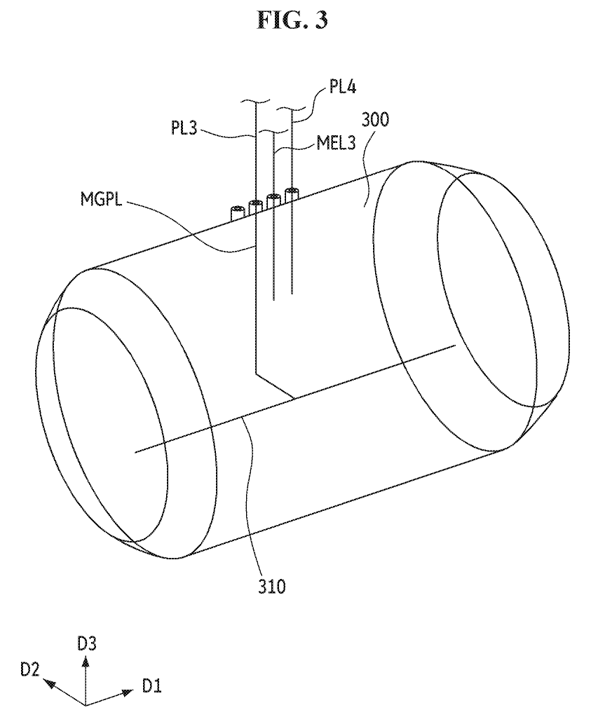

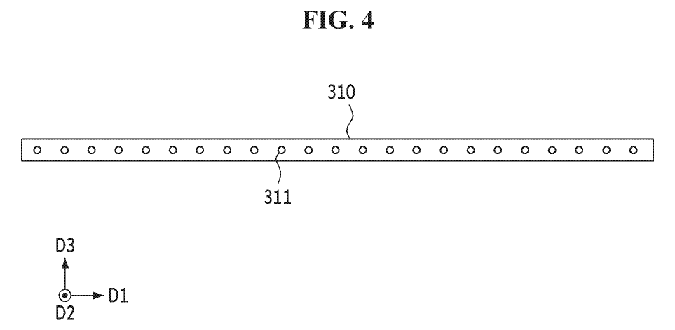

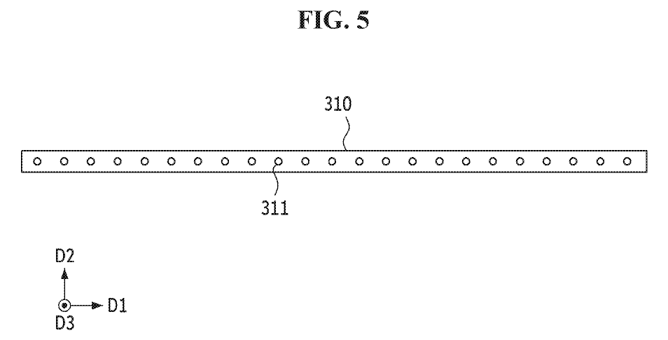

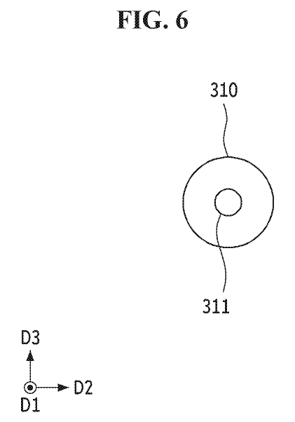

FIG. 3 is a perspective view showing the storage tank shown in FIG. 1. FIGS. 4-6 are diagrams showing the supply nozzle shown in FIG. 3.

With reference to FIGS. 3-6, the storage tank 300 may be connected to the third supply line PL3 and may store one of the mixed gas generated in the first mixing unit 100 and the mixed gas generated in the second mixing unit 200. A storage space for storing one of the mixed gas generated in the first mixing unit 100 and the mixed gas generated in the second mixing unit 200 may be formed inside the storage tank 300.

The gas supply device 10, according to an embodiment of the present disclosure, may further include a mixed gas supply line MGPL and a supply nozzle 310.

The mixed gas supply line MGPL may provide a passage through which the mixed gas flowing through the third supply line PL3 flows into the storage space of the storage tank 300. The mixed gas supply line MGPL may extend from the third supply line PL3 to the internal storage space of the storage tank 300. For example, the mixed gas supply line MGPL may extend from an inner side of the storage space of the storage tank 300 to a central region of the storage space along a third direction D3. The mixed gas supply line MGPL may be provided as a pipe having a flow space formed therein, and one side of the mixed gas supply line MGPL may be connected to the third supply line PL3. The mixed gas flowing through the third supply line PL3 may flow through the internal flow space of the mixed gas supply line MGPL.

The supply nozzle 310 may extend from the mixed gas supply line MGPL. The supply nozzle 310 may extend symmetrically from an extension end of the mixed gas supply line MGPL in both directions. For example, the supply nozzle 310 may extend from the extension end of the mixed gas supply line MGPL to both sides of the first direction D1, which is a direction crossing (e.g., intersecting) the direction in which the mixed gas supply line MGPL extends. The supply nozzle 310 may be provided as a pipe having a flow space formed therein, and an intermediate part thereof may be connected to the mixed gas supply line MGPL. The mixed gas flowing through theb mixed gas supply line MGPL may flow through the internal flow space of the supply nozzle 310.

The supply nozzle 310 may have a plurality of nozzle holes 311 formed therein. The plurality of nozzle holes 311 may be disposed to be spaced apart from each other along the outer periphery of the supply nozzle 310. For example, the plurality of nozzle holes 311 may be formed above and below the supply nozzle 310 in the third direction D3 and may be formed on both sides thereof in the second direction D2. Such nozzle holes 311 may be formed to be spaced apart from each other along a longitudinal direction of the supply nozzle 310, for example, the first direction D1. At least one or more of the plurality of nozzle holes 311 may be formed at both extension ends of the supply nozzle 310. Accordingly, because the nozzle holes 311 are formed on both sides of the supply nozzle 310 in the first direction D1, on both sides thereof in the second direction D2, and both sides thereof in the third direction D3, the mixed gas flowing into the storage space of the storage tank 300 through the supply nozzle 310 may flow through the entire internal region of the storage space. Therefore, the mixed gas flowing into the storage space of the storage tank 300 may be diffused and mixed again in the storage space of the storage tank 300.

Referring to FIG. 1 again, the fourth supply line PL4 may be connected to the storage tank 300 and may provide a passage through the mixed gas stored in the storage tank 300 flows. The fourth supply line PL4 may connect the storage tank 300 and the process chamber 400 and may provide a passage through which the mixed gas stored in the storage tank 300 flows to the process chamber 400. For example, the fourth supply line PL4 may be provided as a pipe having a flow space formed therein. One side of the fourth supply line PL4 may be connected to the storage tank 300, and the other side thereof may be connected to the process chamber 400. The mixed gas stored in the storage tank 300 may flow to the process chamber 400 through the internal flow space of the fourth supply line PL4. The process chamber 400 may be a chamber for various processes for manufacturing a display device. When a plurality of process chambers 400 are provided, the fourth supply line PL4 may branch off into a plurality of lines to be connected to each process chamber 400. For example, when the gas supply device 10 supplies the mixed gas to the plurality of process chambers 400, a plurality of fourth supply lines PL4 may be provided to connect the storage tank 300 to each process chamber 400. In such an embodiment, a fourth flow controller MFC4, which will be described below, may be provided in a number corresponding to the plurality of fourth supply lines PL4 and disposed on each fourth supply line PL4.

The gas supply device 10, according to an embodiment of the present disclosure, may further include a first flow controller MFC1, a second flow controller MFC2, a third flow controller MFC3, and a fourth flow controller MFC4.

The first flow controller MFC1 may be disposed on the first supply line PL1. The first flow controller MFC1 may control the flow rate of the mixed gas flowing through the first supply line PL1.

The second flow controller MFC2 may be disposed on the second supply line PL2. The second flow controller MFC2 may control the flow rate of the mixed gas flowing through the second supply line PL2.

The third flow controller MFC3 may be disposed on the third supply line PL3. The third flow controller MFC3 may control the flow rate of the mixed gas flowing through the third supply line PL3.

The fourth flow controller MFC4 may be disposed on the fourth supply line PL4. The fourth flow controller MFC4 may control the flow rate of the mixed gas flowing through the fourth supply line PL4.

The first main exhaust line MEL1 may be connected to the first mixing unit 100. The first main exhaust line MEL1 may provide a passage for discharging some of the mixed gas generated in the first mixing unit 100. For example, the first main exhaust line MEL1 may be provided as a pipe having a flow space formed therein, and one side of the first main exhaust line MEL1 may be connected to the first mixing unit 100. Some of the mixed gas generated in the first mixing unit 100 may flow through the internal flow space of the first main exhaust line MEL1. The first main exhaust line MEL1 may be connected to the first exhaust line EL1 of the first mixing unit 100.

The second main exhaust line MEL2 may be connected to the second mixing unit 200. The second main exhaust line MEL2 may provide a passage for discharging some of the mixed gas generated in the second mixing unit 200. For example, the second main exhaust line MEL2 may be provided as a pipe having a flow space formed therein, and one side of the second main exhaust line MEL2 may be connected to the second mixing unit 200. Some of the mixed gas generated in the second mixing unit 200 may flow through the internal flow space of the second main exhaust line MEL2. The second main exhaust line MEL2 may be connected to the second exhaust line EL2 of the second mixing unit 200.

The third main exhaust line MEL3 may be connected to the storage tank 300. The third main exhaust line MEL3 may provide a passage for discharging some of the mixed gas stored in the storage tank 300. For example, the third main exhaust line MEL3 may be provided as a pipe having a flow space formed therein, and one side of the third main exhaust line MEL3 may be connected to the storage tank 300. Some of the mixed gas stored in the storage tank 300 may flow through the internal flow space of the third main exhaust line MEL3.

The fourth main exhaust line MEL4 may be connected to the first main exhaust line MEL1, the second main exhaust line MEL2, and the third main exhaust line MEL3. The fourth main exhaust line MEL4 may provide a passage for discharging the mixed gas flowing through the first main exhaust line MEL1, the mixed gas flowing through the second main exhaust line MEL2, and the mixed gas flowing through the third main exhaust line MEL3. For example, the fourth main exhaust line MEL4 may be provided as a pipe having a flow space formed therein. The mixed gas flowing through the first main exhaust line MEL1, the mixed gas flowing through the second main exhaust line MEL2, and the mixed gas flowing through the third main exhaust line MEL3 may flow through the internal flow space of the fourth main exhaust line MEL4.

The controller 500 may control the first mixing unit 100 and the second mixing unit 200 so that the mixed gas is generated only in one of the first mixing unit 100 and the second mixing unit 200. The controller 500 may control the opening and closing of the valves of the first mixing unit 100 and the second mixing unit 200 on the basis of one or more operating modes. The one or more operating modes may include a mixing mode, a first exhaust mode, and a second exhaust mode.

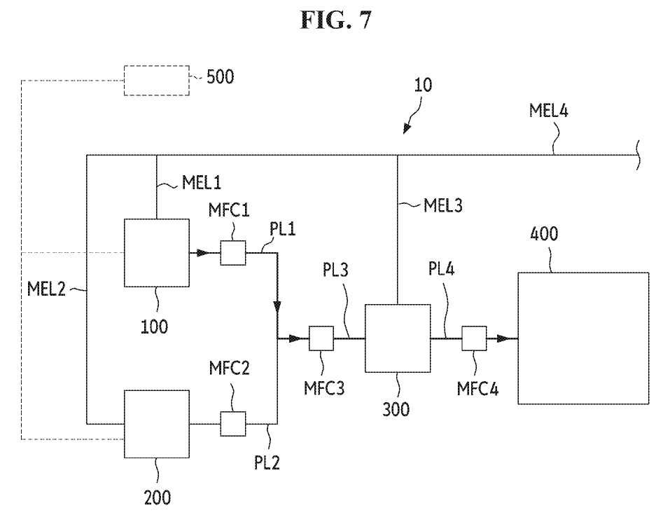

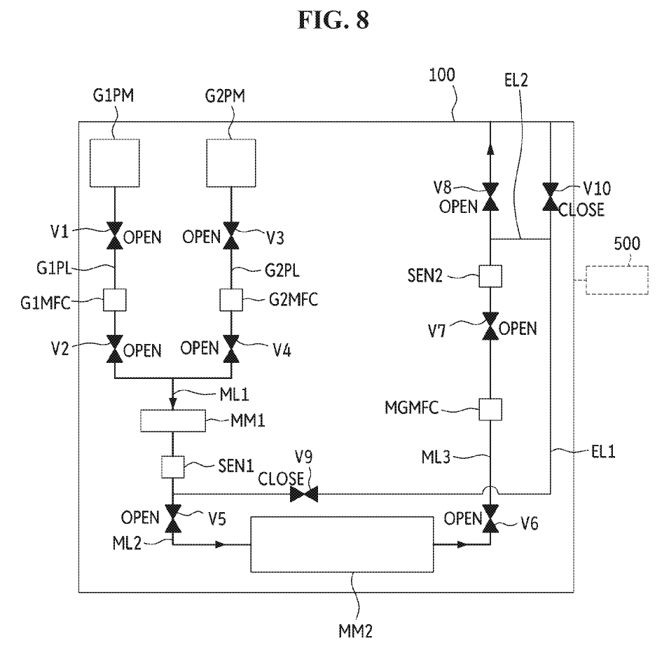

FIG. 7 is a diagram showing a state in which the mixed gas is generated only in the first mixing unit shown in FIG. 1. FIG. 8 is a diagram showing a state in which the first mixing unit shown in FIG. 2 operates in the mixing mode.

Referring to FIGS. 7 and 8, when the first mixing unit 100 operates in the mixing mode, the controller 500 may open the first valve V1, the second valve V2, the third valve V3, and the fourth valve V4 so that the first gas and the second gas flow to the first mixing unit MM1. When the controller 500 opens the first valve V1, the second valve V2, the third valve V3, and the fourth valve V4, the first gas supplied from the first gas supply unit G1PM and the second gas supplied from the second gas supply unit G2PM may flow to the first mixing unit MM1 through the first gas supply line G1PL, the second gas supply line G2PL, and the first mixing line ML1.

The controller 500 may open the fifth valve V5 so that the mixed gas stored in the first mixing unit MM1 flows to the second mixing unit MM2. When the controller 500 opens the fifth valve V5, the mixed gas stored in the first mixing unit MM1 may flow to the second mixing unit MM2 through the second mixing line ML2.

The controller 500 may open the sixth valve V6, the seventh valve V7, and the eighth valve V8 so that the mixed gas stored in the second mixing unit MM2 flows to the third mixing line ML3. When the controller 500 opens the sixth valve V6, the seventh valve V7, and the eighth valve V8, the mixed gas stored in the second mixing unit MM2 may flow through the third mixing line ML3.

The controller 500 may close the ninth valve V9 and the tenth valve V10 so that the first exhaust line EL1 is closed. When the controller 500 closes the ninth valve V9 and the tenth valve V10, the mixed gas flowing through the second mixing line ML2 does not flow to the first exhaust line EL1 but may flow to the second mixing unit MM2 through the second mixing line ML2.

As described above, when the controller 500 controls the valves of the first mixing unit 100, the mixed gas obtained by mixing the first gas and the second gas may flow into the first supply line PL1 through the third mixing line ML3. When the mixed gas is generated in the first mixing unit 100, the controller 500 may close the valves of the second mixing unit 200 to prevent the mixed gas from being generated in the second mixing unit 200.

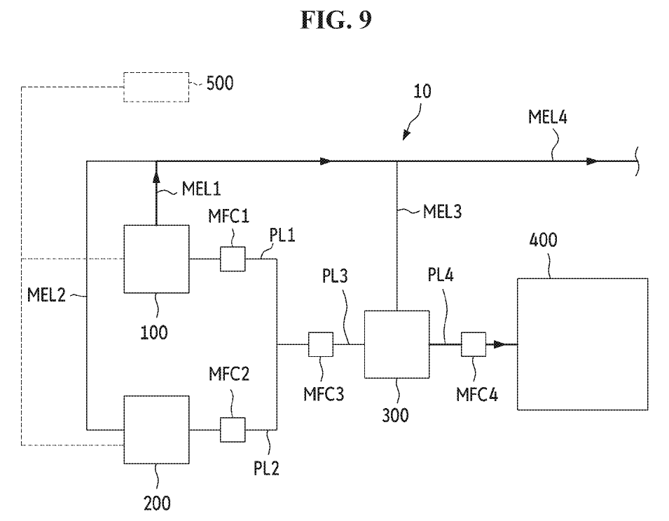

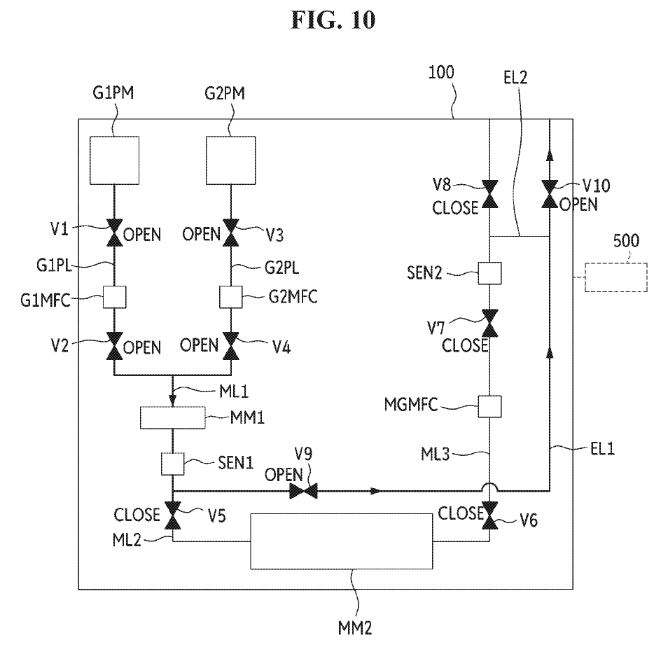

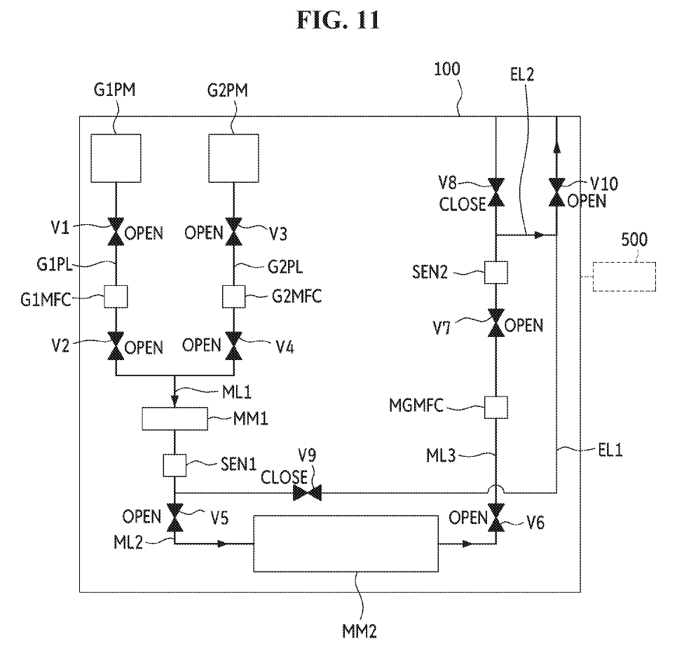

FIG. 9 is a diagram showing a state in which some of the mixed gas generated from the first mixing unit is discharged to the first main exhaust line shown in FIG. 1. FIG. 10 is a diagram showing a state in which the first mixing unit shown in FIG. 2 operates in the first exhaust mode. FIG. 11 is a diagram showing a state in which the first mixing unit shown in FIG. 2 operates in the second exhaust mode.

With reference to FIGS. 9-11, the first mixing unit 100 may operate in the first exhaust mode may when the ratio of the mixed gas flowing through the second mixing line ML2 sensed by the first sensor SEN1 does not match a reference (or preset) mixing ratio. The reference mixing ratio of the mixed gas may vary depending on the process of manufacturing the display device.

When the first mixing unit 100 operates in the first exhaust mode, the controller 500 may open the first valve V1, the second valve V2, the third valve V3, and the fourth valve V4 so that the first gas and the second gas flow to the first mixing unit MM1. When the controller 500 opens the first valve V1, the second valve V2, the third valve V3, and the fourth valve V4, the first gas supplied from the first gas supply unit G1PM and the second gas supplied from the second gas supply unit G2PM may flow into the first mixing unit MM1 through the first gas supply line G1PL, the second gas supply line G2PL, and the first mixing line ML1.

The controller 500 may close the fifth valve V5 and open the ninth valve V9 and the tenth valve V10 so that the mixed gas flowing through the second mixing line ML2 flows into the first exhaust line EL1. When the controller 500 closes the fifth valve V5 and opens the ninth valve V9 and the tenth valve V10, the mixed gas flowing through the second mixing line ML2 does not flow into the second mixing unit MM2 but may flow into the first exhaust line EL1.

The controller 500 may close the sixth valve V6, the seventh valve V7, and the eighth valve V8 so that the mixed gas stored in the second mixing unit MM2 does not flow into the third mixing line ML3. When the controller 500 closes the sixth valve V6, the seventh valve V7, and the eighth valve V8, the mixed gas stored in the second mixing unit MM2 may not flow into the third mixing line ML3.

As described above, when the controller 500 controls the valves of the first mixing unit 100, the mixed gas generated in the first mixing unit 100 may flow into the first main exhaust line MEL1 through the first exhaust line EL1. The mixed gas flowing into the first main exhaust line MEL1 may flow into the fourth main exhaust line MEL4.

The first mixing unit 100 may operate in the second exhaust mode when the ratio of the mixed gas flowing through the third mixing line ML3 sensed by the second sensor SEN2 does not match a reference (or preset) mixing ratio. The reference mixing ratio of the mixed gas may vary depending on the process of manufacturing the display device.

When the first mixing unit 100 operates in the second exhaust mode, the controller 500 may open the first valve V1, the second valve V2, the third valve V3, and the fourth valve V4 so that the first gas and the second gas flow to the first mixing unit MM1. When the controller 500 opens the first valve V1, the second valve V2, the third valve V3, and the fourth valve V4, the first gas supplied from the first gas supply unit G1PM and the second gas supplied from the second gas supply unit G2PM may flow to the first mixing unit MM1 through the first gas supply line G1PL, the second gas supply line G2PL, and the first mixing line ML1.

The controller 500 may open the fifth valve V5 so that the mixed gas stored in the first mixing unit MM1 flows to the second mixing unit MM2. When the controller 500 opens the fifth valve V5, the mixed gas stored in the first mixing unit MM1 may flow into the second mixing unit MM2 through the second mixing line ML2.

The controller 500 may open the sixth valve V6 and the seventh valve V7 so that the mixed gas stored in the second mixing unit MM2 flows to the third mixing line ML3. When the controller 500 opens the sixth valve V6 and the seventh valve V7, the mixed gas stored in the second mixing unit MM2 may flow through the third mixing line ML3.

The controller 500 may close the ninth valve V9 so that the first exhaust line EL1 is closed. When the controller 500 closes the ninth valve V9, the mixed gas flowing through the second mixing line ML2 does not flow to the first exhaust line EL1 but may flow to the second mixing unit MM2 through the second mixing line ML2.

The controller 500 may close the eighth valve V8 and open the tenth valve V10 so that the mixed gas flowing through the third mixing line ML3 flows to the second exhaust line EL2. When the controller 500 closes the eighth valve V8 and opens the tenth valve V10, the mixed gas flowing through the third mixing line ML3 does not flow to the first supply line PL1 but may flow to the first exhaust line EL1 through the second exhaust line EL2.

As described above, when the controller 500 controls the valves of the first mixing unit 100, the mixed gas generated in the first mixing unit 100 may flow to the first main exhaust line MEL1 through the first exhaust line EL1.

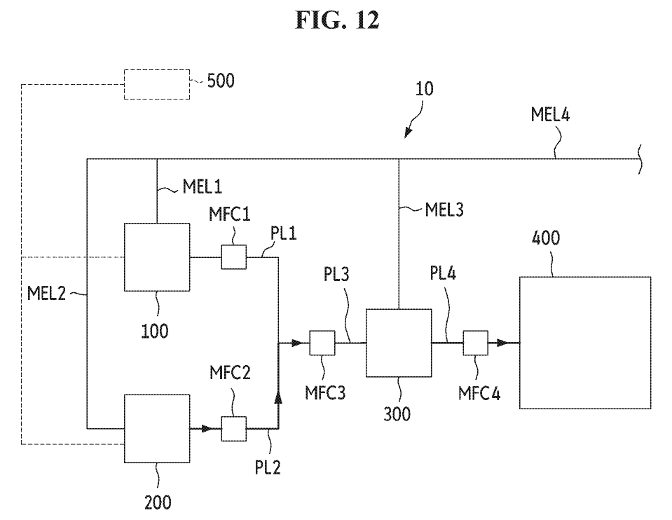

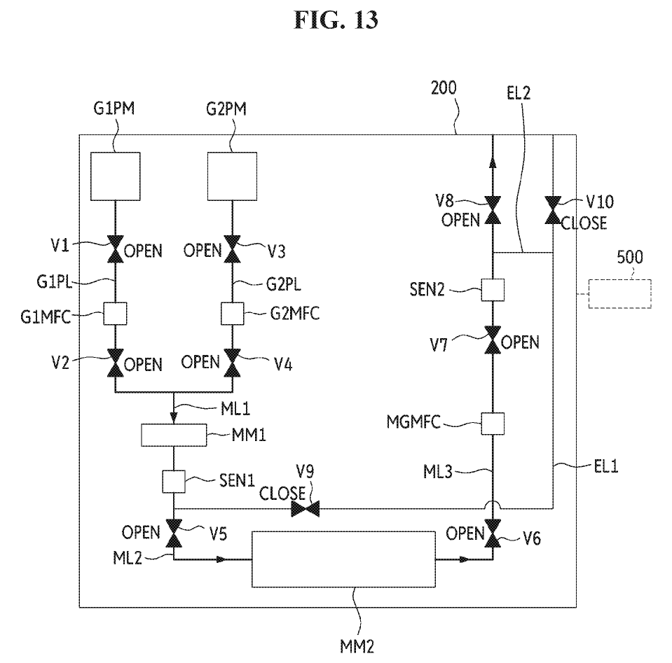

FIG. 12 is a diagram showing a state in which the mixed gas is generated only in the second mixing unit. FIG. 13 is a diagram showing a state in which the second mixing unit shown in FIG. 2 operates in the mixing mode.

With reference to FIGS. 12 and 13, when the second mixing unit 200 operates in the mixing mode, the controller 500 may open the first valve V1, the second valve V2, the third valve V3, and the fourth valve V4 so that the first gas and the second gas flow to the first mixing unit MM1. When the controller 500 opens the first valve V1, the second valve V2, the third valve V3, and the fourth valve V4, the first gas supplied from the first gas supply unit G1PM and the second gas supplied from the second gas supply unit G2PM may flow to the first mixing unit MM1 through the first gas supply line G1PL, the second gas supply line G2PL, and the first mixing line ML1.

The controller 500 may open the fifth valve V5 so that the mixed gas stored in the first mixing unit MM1 flows to the second mixing unit MM2. When the controller 500 opens the fifth valve V5, the mixed gas stored in the first mixing unit MM1 may flow to the second mixing unit MM2 through the second mixing line ML2.

The controller 500 may open the sixth valve V6, the seventh valve V7, and the eighth valve V8 so that the mixed gas stored in the second mixing unit MM2 flows to the third mixing line ML3. When the controller 500 opens the sixth valve V6, the seventh valve V7, and the eighth valve V8, the mixed gas stored in the second mixing unit MM2 may flow through the third mixing line ML3.

The controller 500 may close the ninth valve V9 and the tenth valve V10 so that the first exhaust line EL1 is closed. When the controller 500 closes the ninth valve V9 and the tenth valve V10, the mixed gas flowing through the second mixing line ML2 does not flow to the first exhaust line EL1 but may flow to the second mixing unit MM2 through the second mixing line ML2.

As described above, when the controller 500 controls the valves of the second mixing unit 200, the mixed gas obtained by mixing the first gas and the second gas may flow to the second supply line PL2 through the third mixing line ML3. When the mixed gas is generated in the second mixing unit 200, the controller 500 may close the valves of the first mixing unit 100 to prevent the mixed gas from being generated in the first mixing unit 100.

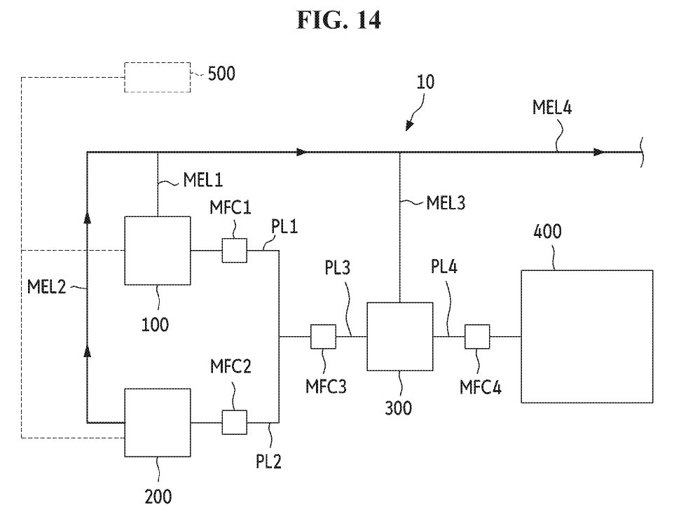

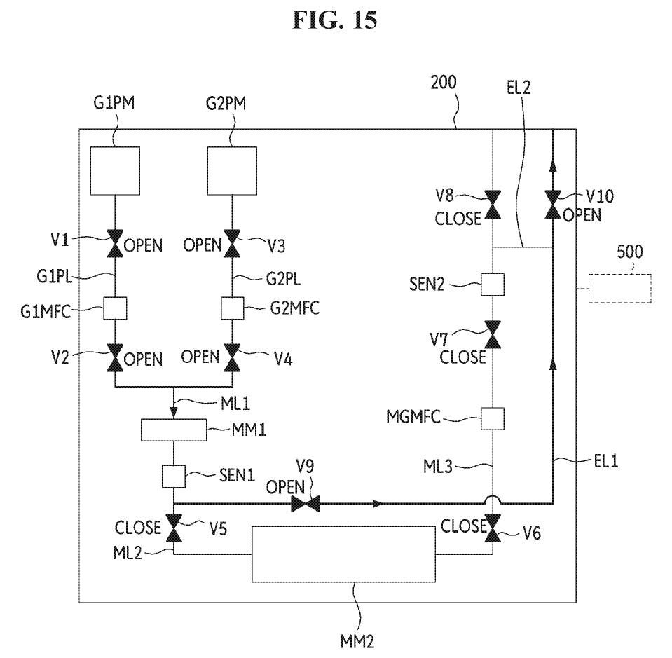

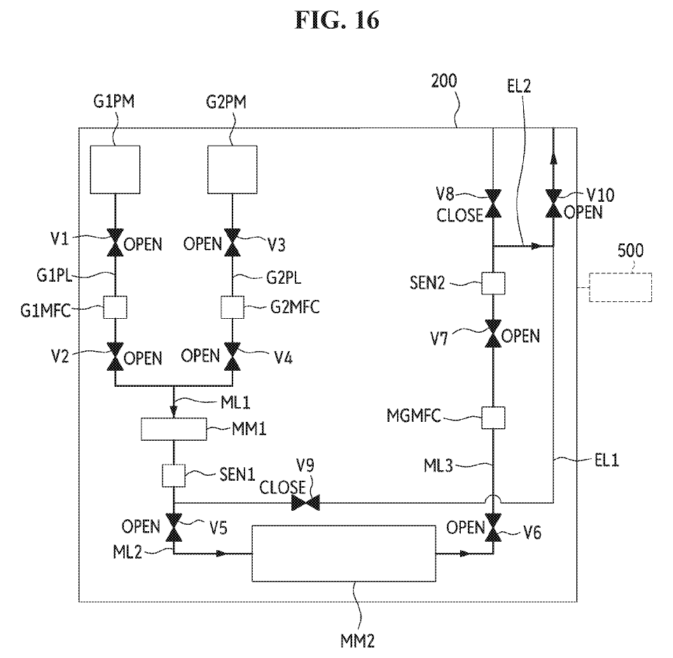

FIG. 14 is a diagram showing a state in which some of the mixed gas generated from the second mixing unit is discharged to the second main exhaust line shown in FIG. 1. FIG. 15 is a diagram showing a state in which the second mixing unit shown in FIG. 2 operates in the first exhaust mode. FIG. 16 is a diagram showing a state in which the second mixing unit shown in FIG. 2 operates in the second exhaust mode.

With reference to FIGS. 14-16, the second mixing unit 200 may operate in the first exhaust mode when the ratio of the mixed gas flowing through the second mixing line ML2 sensed by the first sensor SEN1 does not match a reference (or preset) mixing ratio. The reference mixing ratio of the mixed gas may vary depending on the process of manufacturing the display device.

When the second mixing unit 200 operates in the first exhaust mode, the controller 500 may open the first valve V1, the second valve V2, the third valve V3, and the fourth valve V4 so that the first gas and the second gas flow to the first mixing unit MM1. When the controller 500 opens the first valve V1, the second valve V2, the third valve V3, and the fourth valve V4, the first gas supplied from the first gas supply unit G1PM and the second gas supplied from the second gas supply unit G2PM may flow to the first mixing unit MM1 through the first gas supply line G1PL, the second gas supply line G2PL, and the first mixing line ML1.

The controller 500 may close the fifth valve V5 and open the ninth valve V9 and the tenth valve V10 so that the mixed gas flowing through the second mixing line ML2 flows into the first exhaust line EL1. When the controller 500 closes the fifth valve V5 and opens the ninth valve V9 and the tenth valve V10, the mixed gas flowing through the second mixing line ML2 does not flow into the second mixing unit MM2 but may flow into the first exhaust line EL1.

The controller 500 may close the sixth valve V5, the seventh valve V7, and the eighth valve V8 so that the mixed gas stored in the second mixing unit MM2 does not flow into the third mixing line ML3. When the controller 500 closes the sixth valve V5, the seventh valve V7, and the eighth valve V8, the mixed gas stored in the second mixing unit MM2 may not flow into the third mixing line ML3.

As described above, when the controller 500 controls the valves of the second mixing unit 200, the mixed gas generated in the second mixing unit 200 may flow to the second main exhaust line MEL2 through the first exhaust line EL1. The mixed gas flowing to the second main exhaust line MEL2 may flow to the fourth main exhaust line MEL4.

The second mixing unit 200 may operates in the second exhaust mode when the ratio of the mixed gas flowing through the third mixing line ML3 sensed by the second sensor SEN2 does not match a reference (or preset) mixing ratio. The r mixing ratio of the mixed gas may vary depending on the process of manufacturing the display device.

When the second mixing unit 200 operates in the second exhaust mode, the controller 500 may open the first valve V1, the second valve V2, the third valve V3, and the fourth valve V4 so that the first gas and the second gas flow into the first mixing unit MM1. When the controller 500 opens the first valve V1, the second valve V2, the third valve V3, and the fourth valve V4, the first gas supplied from the first gas supply unit G1PM and the second gas supplied from the second gas supply unit G2PM may flow to the first mixing unit MM1 through the first gas supply line G1PL, the second gas supply line G2PL, and the first mixing line ML1.

The controller 500 may open the fifth valve V5 so that the mixed gas stored in the first mixing unit MM1 flows to the second mixing unit MM2. When the controller 500 opens the fifth valve V5, the mixed gas stored in the first mixing unit MM1 may flow to the second mixing unit MM2 through the second mixing line ML2.

The controller 500 may open the sixth valve V6 and the seventh valve V7 so that the mixed gas stored in the second mixing unit MM2 flows to the third mixing line ML3. When the controller 500 opens the sixth valve V6 and the seventh valve V7, the mixed gas stored in the second mixing unit MM2 may flow through the third mixing line ML3.

The controller 500 may close the ninth valve V9 so that the first exhaust line EL1 is closed. When the controller 500 closes the ninth valve V9, the mixed gas flowing through the second mixing line ML2 does not flow to the first exhaust line EL1 but may flow to the second mixing unit MM2 through the second mixing line ML2.

The controller 500 may close the eighth valve V8 and open the tenth valve V10 so that the mixed gas flowing through the third mixing line ML3 flows to the second exhaust line EL2. When the controller 500 closes the eighth valve V8 and opens the tenth valve V10, the mixed gas flowing through the third mixing line ML3 does not flow to the first supply line PL1 but may flow to the first exhaust line EL1 through the second exhaust line EL2.

As described above, when the controller 500 controls the valves of the second mixing unit 200, the mixed gas generated in the second mixing unit 200 may flow through the first exhaust line EL1 to the second main exhaust line MEL2. The mixed gas flowing into the second main exhaust line MEL2 may flow into the fourth main exhaust line MEL4.

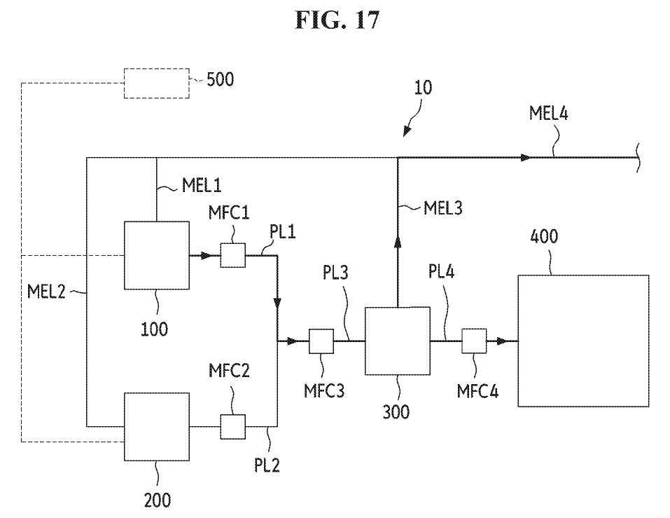

FIG. 17 is a diagram showing a state in which some of the mixed gas stored in the storage tank is discharged to the third main exhaust line shown in FIG. 1.

With reference to FIG. 17, in a state in which the mixed gas generated in the first mixing unit 100 flows continuously into the storage tank 300, when the mixed gas stored in the storage tank 300 exceeds a reference (or preset) storage capacity, some of the mixed gas stored in the storage tank 300 may flow through the third main exhaust line MEL3. The mixed gas flowing into the third main exhaust line MEL3 may flow into the fourth main exhaust line MEL4.

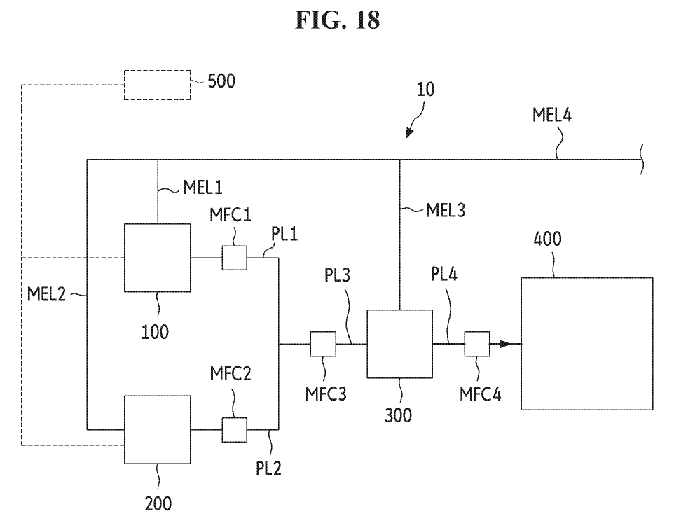

FIG. 18 is a diagram showing a state in which the mixed gas is not generated in the first mixing unit and the second mixing unit shown in FIG. 1.

Referring to FIG. 18, even if a problem occurs in the first mixing unit 100 and the second mixing unit 200 and the operation of the first mixing unit 100 and the second mixing unit 200 stops, the mixed gas stored in the storage tank 300 may flow to the process chamber 400 through the fourth supply line PL4. Therefore, even if a failure occurs in the first mixing unit 100 and the second mixing unit 200 and the operation stops, because the mixed gas stored in the storage tank 300 is continuously supplied to the process chamber 400, the mixed gas may be stably supplied to the process chamber 400. While the mixed gas stored in the storage tank 300 is being supplied to the process chamber 400, repairs of the first mixing unit 100 and the second mixing unit 200 can be performed.

The gas supply device 10, according to an embodiment of the present disclosure, generates the mixed gas in only one of the first mixing unit 100 and the second mixing unit 200 and supplies the mixed gas to the process chamber 400. Therefore, even if a problem occurs in the first mixing unit 100 or the second mixing unit 200, because the mixed gas is continuously generated in the other mixing unit and supplied to the process chamber 400, the mixed gas can be stably supplied to the process chamber 400.

The controller and/or any other relevant devices or components according to embodiments of the present disclosure described herein may be implemented utilizing any suitable hardware, firmware (e.g., an application-specific integrated circuit), software, and/or a suitable combination of software, firmware, and hardware. For example, the various components of the controller may be formed on one integrated circuit (IC) chip or on separate IC chips. Further, the various components of the controller may be implemented on a flexible printed circuit film, a tape carrier package (TCP), a printed circuit board (PCB), or formed on a same substrate as the controller. Further, the various components of the controller may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device or the functionality of a particular computing device may be distributed across one or more other computing devices without departing from the scope of the exemplary embodiments of the present disclosure.

It should be understood, however, that aspects and features of embodiments of the present disclosure are not limited to those set forth herein. The above and other aspects and features of the present disclosure will become more apparent to one of ordinary skill in the art to which the present disclosure pertains by referencing the claims, with equivalents thereof to be included therein.

What is claimed is:

1. A gas supply device comprising:
a first mixing unit configured to mix a first gas and a second gas to generate a mixed gas;
a first supply line connected to the first mixing unit and providing a passage through which the mixed gas generated by the first mixing unit flows;
a second mixing unit configured to mix the first gas and the second gas to generate the mixed gas;
a second supply line connected to the second mixing unit and providing a passage through which the mixed gas generated by the second mixing unit flows;
a third supply line connected to the first supply line and the second supply line and providing a passage through which one of the mixed gas generated by the first mixing unit and the mixed gas generated by the second mixing unit flows;
a storage tank connected to the third supply line and configured to store one of the mixed gas generated by the first mixing unit and the mixed gas generated by the second mixing unit;
a fourth supply line connected to the storage tank and providing a passage through which the mixed gas stored in the storage tank flows; and
a controller configured to control the first mixing unit and the second mixing unit so that the mixed gas is selectively generated in either the first mixing unit or the second mixing unit.

2. The gas supply device of claim 1, further comprising:
a first flow controller disposed on the first supply line and configured to control a flow rate of the mixed gas generated in the first mixing unit flowing through the first supply line;
a second flow controller disposed on the second supply line and configured to control a flow rate of the mixed gas generated in the second mixing unit and flowing through the second supply line;
a third flow controller disposed on the third supply line and configured to control a flow rate of one of the mixed gas generated in the first mixing unit and the mixed gas generated in the second mixing unit and flowing through the third supply line; and
a fourth flow controller disposed on the fourth supply line and configured to control a flow rate of the mixed gas stored in the storage tank and flowing through the fourth supply line.

3. The gas supply device of claim 2, further comprising:
a first main exhaust line connected to the first mixing unit and providing a passage for discharging some of the mixed gas generated in the first mixing unit;
a second main exhaust line connected to the second mixing unit and providing a passage for discharging some of the mixed gas generated in the second mixing unit;
a third main exhaust line connected to the storage tank and providing a passage for discharging some of the mixed gas stored in the storage tank; and
a fourth main exhaust line connected to the first main exhaust line, the second main exhaust line, and the third main exhaust line and providing a passage for discharging some of the mixed gas generated in the first mixing unit, some of the mixed gas generated in the second mixing unit, and some of the mixed gas stored in the storage tank.

4. The gas supply device of claim 3, wherein each of the first mixing unit and the second mixing unit comprises:
a first gas supply unit configured to supply the first gas;
a first gas supply line connected to the first gas supply unit and provides a passage through which the first gas supplied from the first gas supply unit flows;
a second gas supply unit configured to supply the second gas;
a second gas supply line connected to the second gas supply unit and providing a passage through which the second gas supplied from the second gas supply unit flows;
a first mixing line connected to the first gas supply line and the second gas supply line and providing a passage through which the first gas flowing through the first gas supply line and the second gas flowing through the second gas supply line flow;
a first mixing unit connected to the first mixing line and having a storage space for mixing and storing the first gas and second gas flowing through the first mixing line formed therein;
a second mixing line connected to the first mixing unit and providing a passage through which the mixed gas mixed in the first mixing unit flows;
a second mixing unit connected to the second mixing line and having a storage space for remixing and storing the mixed gas flowing through the second mixing line formed therein; and
a third mixing line connected to the second mixing unit and providing a passage through which the mixed gas mixed in the second mixing unit flows.

5. The gas supply device of claim 4, wherein the storage space of the first mixing unit is smaller than the storage space of the second mixing unit.

6. The gas supply device of claim 4, wherein each of the first mixing unit and the second mixing unit comprises:
a first sensor disposed on the second mixing line and configured to determine a mixing ratio of the mixed gas flowing through the second mixing line;
a second sensor disposed on the third mixing line and configured to determine the mixing ratio of the mixed gas flowing through the third mixing line;
a first exhaust line branching off from the second mixing line downstream of the first sensor in a flow direction of the mixed gas and providing a passage for discharging the mixed gas flowing through the second mixing line; and
a second exhaust line branching off from the third mixing line downstream of the second sensor in the flow direction of the mixed gas, is connected to the first exhaust line, and providing a passage for discharging the mixed gas flowing through the third mixing line to the first exhaust line.

7. The gas supply device of claim 6, wherein each of the first mixing unit and the second mixing unit comprises:
a first gas flow controller disposed on the first gas supply line and configured to control the flow rate of the first gas flowing through the first gas supply line;
a second gas flow controller disposed on the second gas supply line and configured to control the flow rate of the second gas flowing through the second gas supply line; and
a mixed gas flow controller disposed on the third mixing line, disposed upstream of the second sensor in the flow direction of the mixed gas, and configured to control the flow rate of the mixed gas flowing through the third mixing line.

8. The gas supply device of claim 7, wherein each of the first mixing unit and the second mixing unit comprises:
a first valve disposed on the first gas supply line upstream of the first gas flow controller in the flow direction of the first gas;
a second valve disposed on the first gas supply line downstream of the first gas flow controller in the flow direction of the first gas;
a third valve disposed on the second gas supply line upstream of the second gas flow controller in the flow direction of the second gas;
a fourth valve disposed on the second gas supply line downstream of the second gas flow controller in the flow direction of the second gas;
a fifth valve disposed on the second mixing line downstream of a point at where the first exhaust line branches off in the flow direction of the mixed gas;
a sixth valve disposed on the third mixing line upstream of the mixed gas flow controller in the flow direction of the mixed gas;
a seventh valve disposed on the third mixing line between the mixed gas flow controller and the second sensor;
an eighth valve disposed on the third mixing line downstream of a point at where the second exhaust line branches off in the flow direction of the mixed gas;
a ninth valve disposed on the first exhaust line upstream of a point at where the second exhaust line is connected in the flow direction of the mixed gas; and
a tenth valve disposed on the first exhaust line downstream of a point at where the second exhaust line is connected in the flow direction of the mixed gas, and
wherein the controller is configured to control the opening and closing of the valves according to one or more operating modes.

9. The gas supply device of claim 8, wherein the one or more operating modes comprises a mixing mode, and
wherein, during the mixing mode:
the controller is configured to open the first valve, the second valve, the third valve, and the fourth valve so that the first gas and the second gas flow to the first mixing unit,
the controller is configured to open the fifth valve so that the mixed gas stored in the first mixing unit flows to the second mixing unit,
the controller is configured to open the sixth valve, the seventh valve, and the eighth valve so that the mixed gas stored in the second mixing unit flows to the third mixing line, and
the controller is configured to close the ninth valve and the tenth valve so that the first exhaust line is closed.

10. The gas supply device of claim 8, wherein the one or more operating modes comprises a first exhaust mode, and
wherein, during the first exhaust mode:
the controller is configured to open the first valve, the second valve, the third valve, and the fourth valve so that the first gas and the second gas flow to the first mixing unit,
the controller is configured to close the fifth valve and open the ninth and tenth valves so that the mixed gas flowing through the second mixing line flows to the first exhaust line, and
the controller is configured to close the sixth valve, the seventh valve, and the eighth valve so that the mixed gas stored in the second mixing unit does not flow to the third mixing line.

11. The gas supply device of claim 10, wherein, when the mixing ratio of the mixed gas flowing through the second mixing line determined by the first sensor does not match a reference mixing ratio, the controller is configured to control the opening and closing of the valves according to the first exhaust mode.

12. The gas supply device of claim 8, wherein the one or more operating modes comprises a second exhaust mode, and
wherein, during the second exhaust mode:
the controller is configured to open the first valve, the second valve, the third valve, and the fourth valve so that the first gas and the second gas flow to the first mixing unit,
the controller is configured to open the fifth valve so that the mixed gas stored in the first mixing unit flows to the second mixing unit,
the controller is configured to open the sixth valve and the seventh valve so that the mixed gas stored in the second mixing unit flows to the third mixing line,
the controller is configured to close the ninth valve so that the mixed gas flowing through the second mixing line does not flow to the first exhaust line, and
the controller is configured to close the eighth valve and opens the tenth valve so that the mixed gas flowing through the eighth mixing line flows to the first exhaust line through the second exhaust line.

13. The gas supply device of claim 12, wherein, when the mixing ratio of the mixed gas flowing through the third mixing line determined by the second sensor does not match the reference mixing ratio, the controller is configured to control the opening and closing of the valves according to the second exhaust mode.

14. The gas supply device of claim 6, wherein the third mixing line of the first mixing unit is connected to the first supply line,
wherein the first exhaust line of the first mixing unit is connected to the first main exhaust line,
wherein the third mixing line of the second mixing unit is connected to the second supply line, and
wherein the first exhaust line of the second mixing unit is connected to the second main exhaust line.

15. The gas supply device of claim 3, wherein when the mixed gas stored in the storage tank exceeds a reference storage capacity, some of the mixed gas stored in the storage tank is discharged through the third main exhaust line.

16. The gas supply device of claim 1, wherein the storage tank has a storage space for storing one of the mixed gas generated by the first mixing unit and the mixed gas generated by the second mixing unit, and
wherein the gas supply device further comprises:
a mixed gas supply line extending from the third supply line to the storage space of the storage tank; and
a supply nozzle extending from the mixed gas supply line and having a plurality of nozzle holes formed therein.

17. The gas supply device of claim 16, wherein the supply nozzle extends in a direction crossing a direction in which the mixed gas supply line extends.

18. The gas supply device of claim 16, wherein the mixed gas supply line extends from an inner side of the storage space of the storage tank to a central region of the storage space, and
wherein the supply nozzle extends symmetrically from extension ends of the mixed gas supply line in opposite directions.

19. The gas supply device of claim 16, wherein the plurality of nozzle holes are spaced apart from each other along an outer periphery and an extension direction of the supply nozzle.

20. The gas supply device of claim 19, wherein some of the plurality of nozzle holes are formed at both extension ends of the supply nozzle.
